(19) United States
(12) Patent Application Publication
(10) Pub. No.: US 2018/0047887 A1
(43) Pub. Date: Feb. 15, 2018

(54) Multi-stage thermoelectric generator monolithically integrated on a light absorber

(71) Applicant: The Regents the University of California, Oakland, CA (US)

(72) Inventors: Nobuhiko KOBAYASHI, Sunnyvale, CA (US); Kate J. CREMATA, Los Altos, CA (US)

(21) Appl. No.: 15/552,355

(22) PCT Filed: Feb. 10, 2016
(86) PCT No.: PCT/US2016/017314

§ 371 Date: Aug. 21, 2017

Related U.S. Application Data
(60) Provisional application No. 62/121,058, filed on Feb. 26, 2015.

(51) Int. Cl. H01L 35/30; H01L 35/02; H01L 35/32

(52) U.S. Cl. CPC H01L 35/30; H01L 35/325; H01L 35/02; H01L 35/16

(57) ABSTRACT

A solar-powered thermoelectric generator is provided that includes a solar collector, a light absorbing and heat generating element having an elongated shape, where a first end of the light absorbing and heat generating element is configured to absorb light from the solar collector, where the absorbed light converts to heat in the light absorbing and heat generating element, where the light absorbing and heat generating element is configured to form a thermal gradient along a length of the light absorbing and heat generating element from the first end of the light absorbing and heat generating element to a second end of the light absorbing and heat generating element, and a plurality of thermoelectric generators disposed along the light absorbing and heat generating element, where the first end of the light absorbing and heat generating element is hotter than the second end of the light absorbing and heat generating element.

### FIELD OF THE INVENTION

The present invention relates generally to thermoelectric generators (TEGs). More particularly, the invention relates to Solar TEG (STEG) having a large temperature gradient and multiple TE materials.

### BACKGROUND OF THE INVENTION

Reducing the usage of imported energy and energy-related emissions is of paramount importance worldwide. Supplementing existing technologies that use concentrated sunlight (CS), and substituting a large portion of future implementation of emerging technologies that exploit CS is a fundamental step towards sustainable energy.

Sunlight can be densified through use of optical concentration (Csun), providing a strategy for cost reduction in concentrated photovoltaics (CPV). Energy conversion in CPV comes with an undesirable byproduct, waste heat. The amount of waste heat increases as Csun intensifies, which brings an elaborate scheme in which CPV is coupled with another direct energy conversion (DEC) technology, thermoelectrics (TE), referred to as CPV/TE. The highest Csun at which CPV remains operational depends on available cooling systems that keep the photovoltaic (PV) cell temperature below the maximum operational temperature (Tₘₐₓ). Similarly, the highest Csun for CPV/TE with available cooling systems forcibly sets Tₘₐₓ that unfavorably limits the heat source temperature for the TE part in CPV/TE; thus, it is clear that the current CPV and CPV/TE known in the art do not take full advantage of CS.

While CPV/TE appears to be ideal for harvesting energy at a given Csun, there would be a breakpoint in Cₛᵤₙ beyond which solely using TE becomes both technologically and economically logical, leading to the emergence of concentrated TE (CTE) where TE is driven by CS. Without PV, CTE would utilize Cₛᵤₙ much higher than those limited in CPV and CPV/TE. In a prior art CTE shown in FIG. 1 (Tₕ and T_{c} represent steady-state temperatures on the hot and cold side, respectively), TE generators (TEGs) deal with the following factors; (1) open-circuit voltage is related to the temperature difference (DT) around an operational temperature, (2) short-circuit current is limited by the series electrical resistance, and (3) performance of a specific TE material peaks within a particular temperature range. These three factors often become mutually problematic because of the following inherent design issues (i.e. “technical challenges”) existing in conventional TEGs: (1) DT is, as seen in FIG. 1, generated within a TEG and (2) three-dimensional scaling is hardly feasible, which severely restricts the full-utilization of CS in CTE where conventional TEGs serve as a light absorber.

What is needed is a transformational technology for generating electricity from a renewable energy source (i.e. sunlight) for various stationary applications.

### SUMMARY OF THE INVENTION

To address the needs in the art, a solar-powered thermoelectric generator is provided that includes a solar collector, a light absorbing and heat generating element, where the light absorbing and heat generating element has an elongated shape, where a first end of the light absorbing and heat generating element is configured to absorb light from the solar collector, where the absorbed light converts to heat in the light absorbing and heat generating element, where the light absorbing and heat generating element is configured to form a thermal gradient along a length of the light absorbing and heat generating element from the first end of the light absorbing and heat generating element to a second end of the light absorbing and heat generating element, and a plurality of thermoelectric generators disposed along the light absorbing and heat generating element, where the first end of the light absorbing and heat generating element is hotter than the second end of the light absorbing and heat generating element.

In one aspect of the invention, the light absorbing and heat generating element comprises a material includes those containing a single element (e.g. graphite made of carbon), containing a few primary elements (e.g. Inconel superalloy), and those being in the category of oxides (e.g. aluminum oxide), nitrides (e.g. aluminum nitride), and carbides (e.g. silicon carbide) and their respective compounds either in their crystalline phases or non-crystalline phases.

According to another aspect of the invention, the thermoelectric generator includes at least one p-type semiconductor and at least one n-type semiconductor, where each p-type semiconductor and each n-type semiconductor abut a planar surface of the light absorbing and heat generating element.

In a further aspect of the invention, the thermoelectric generator includes a microcrystal TE film deposited on an insulator foil. An insulator foil refers to those that are either thermally or electrically insulating, or those that are both thermally and electrically insulating. In one aspect, the microcrystal TE film is a material that includes those containing group III and V (e.g. gallium arsenide), group II and VI (zinc oxide), group V and VI (e.g. BiTe), and group IV (e.g Si, Ge) on the Periodic Table. In a further aspect, the thermoelectric generator includes a stack of at least two microcrystal TE films deposited on the insulator foil. In another aspect, the insulator foil is a material that includes oxides (e.g. aluminum oxide), nitrides (e.g. aluminum nitride), and carbides (e.g. silicon carbide) and their respective compounds either in their crystalline phases or non-crystalline phases.

In a further aspect of the invention, the thermoelectric generator includes a microcrystal TE film deposited on a conductor foil. A conductor foil refers to those that are either thermally or electrically conducting, or those that are both thermally and electrically conducting. In one aspect, the microcrystal TE film is a material that includes those containing group III and V (e.g. gallium arsenide), group II and VI (zinc oxide), group V and VI (e.g. BiTe), and group IV (e.g Si, Ge) on the Periodic Table. In a further aspect, the thermoelectric generator includes a stack of at least two microcrystal TE films deposited on the conductor foil. In another aspect, the conductor foil is a material that includes transparent conducting oxides (e.g. indium tin oxide), nitrides (e.g. titanium nitride), and carbides (e.g. tungsten carbide) and their respective compounds either in their crystalline phases or non-crystalline phases.

According to another aspect of the invention, each thermoelectric generator is configured to wrap around the light absorbing and heat generating element.

In yet another aspect of the invention, each thermoelectric generator is configured to match a temperature range along the light absorbing and heat generating element.

In a further aspect of the invention, each thermoelectric generator is disposed longitudinally to the light absorbing and heat generating element.

According to another aspect of the invention, each thermoelectric generator is disposed transverse to the light absorbing and heat generating element.

In another aspect of the invention, the solar-powered thermoelectric generator is coupled to a heat sink, where the heat sink conducts heat from the light absorbing and heat generating element and through the thermoelectric generator.

### BRIEF DESCRIPTION OF THE DRAWINGS

FIG. 1 shows prior art CTE with a conventional TEG.

FIG. 2 shows that a light absorber/heat generator (LAHG) creates ΔT along its length when illuminated by CS, where the LAHG can have an arbitrary shape and does not have to be rectangular prism, according to one embodiment of the invention.

FIGS. 3A-3B show (3A) L-TEG, (3B) V-TEG, according to embodiments of the invention.

FIG. 4 shows experimental current-voltage and power profiles of (1) quadruple-stack, (2) double-stack, and (3) single-stack module, according to embodiments of the invention.

FIGS. 5A-5B show two examples of the invention with (5A) L-TEGs and (5B) V-TEGs, according to embodiments of the invention.

FIG. 6A-6B show SSFE analysis of two SAMTEG examples with (6A) L-TEGs and (6B) V-TEGs, according to embodiments of the invention.

FIGS. 7A-7C show different configurations exemplifying the invention.

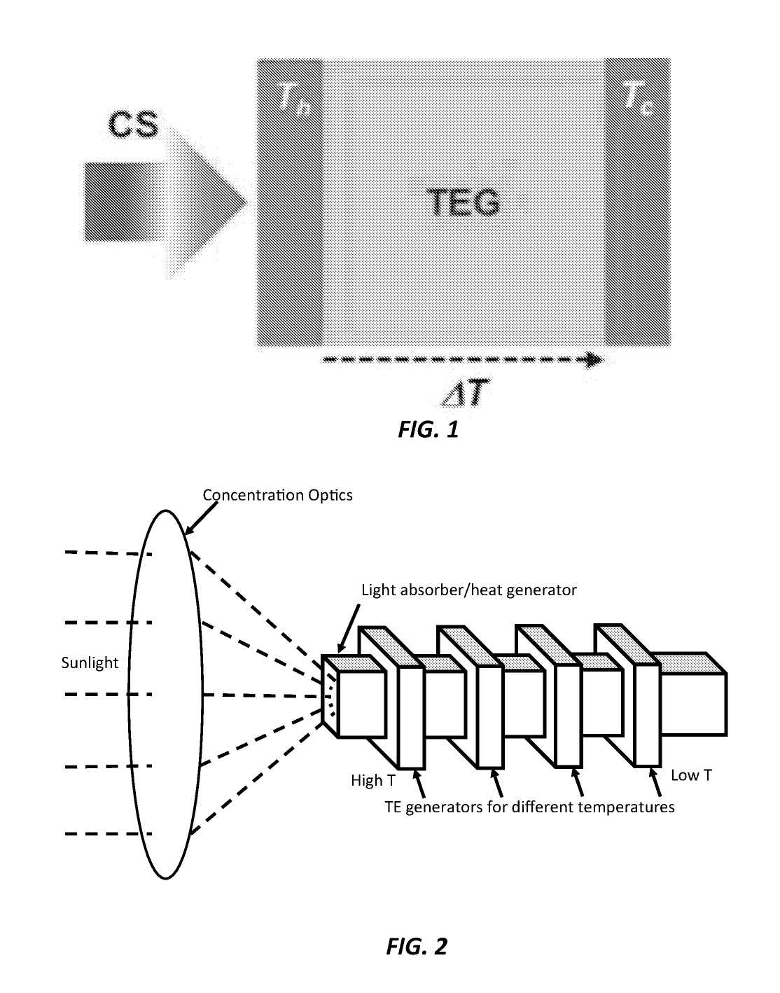

### DETAILED DESCRIPTION

The current invention is a device that maximizes input energy, referred to herein as concentrated sunlight (CS). In one embodiment, nearly the entire solar spectrum contributes to generate a range of temperatures not apt for conventional “direct-energy-conversion” technologies. Here, “direct-energy-conversion (DEC)” refers to a process by which the absorption of CS results in the generation of electrical energy without the involvement of mechanical work.

The current invention exploits the full potential of CS by monolithically integrating an efficient sunlight absorber with an innovative multiple-stage thermoelectric generator. The current invention enables multiple energy opportunities for stationary electrical power generation, which include a range of implementation scales from residential to utility. The current invention explicitly addresses the two technical challenges described above to accomplish the identified energy opportunities. The current invention includes a sunlight absorber that is separated from energy convertors with respect to the primary heat conduction, and provides a new feature in CPV and CPV/TE, and CTE with TEG technologies that utilize CS. The current invention maximizes utilization of high temperatures without the need for complex cooling systems that are generally required in CPV, CPV/TE and conventional CTE.

According to one embodiment, the invention achieves higher efficiency by employing multiple TE materials with average figure-of-merit ZT=1 to be 15˜20% for ΔT=500˜800K at Tₘₐₓ=800˜1100K. The current invention reduces the overall complexity of energy conversion devices by eliminating the need for a cooling system and a PV's, with higher efficiencies than conventional TEGs. The current invention provides a levelized cost of energy that is lower than CPV/TE, and CTE with conventional TEGs. In addition, because the invention has no cooling system and no exotic pn-junctions made of expensive semiconductors, the structural and material simplicities enable the levelized cost of energy to be lower than that of CPV even though advanced PV cells offer the efficiency above 40%.

According to one embodiment, the invention includes two core parts: a sunlight absorber that converts CS into heat and multiple-stage TEGs that convert heat into electrical energy. A light absorber/heat generator was fabricated that creates ΔT along its length when illuminated by CS. Here, the light absorber/heat generator can have an arbitrary shape and does not have to be rectangular prism. Temperature (T) distribution across a light absorber/heat generator can be flexibly designed by tuning relevant geometries and by adjusting thermal interaction between a light absorber/heat generator and its environment. A light absorber/heat generator provides a wide range of temperatures that can be “tapped” by placing multiple TEGs.

In one aspect of the invention, the light absorbing and heat generating element is a material includes those containing a single element (e.g. graphite made of carbon), containing a few primary elements (e.g. Inconel superalloy), and those being in the category of oxides (e.g. aluminum oxide), nitrides (e.g. aluminum nitride), and carbides (e.g. silicon carbide) and their respective compounds either in their crystalline phases or non-crystalline phases.

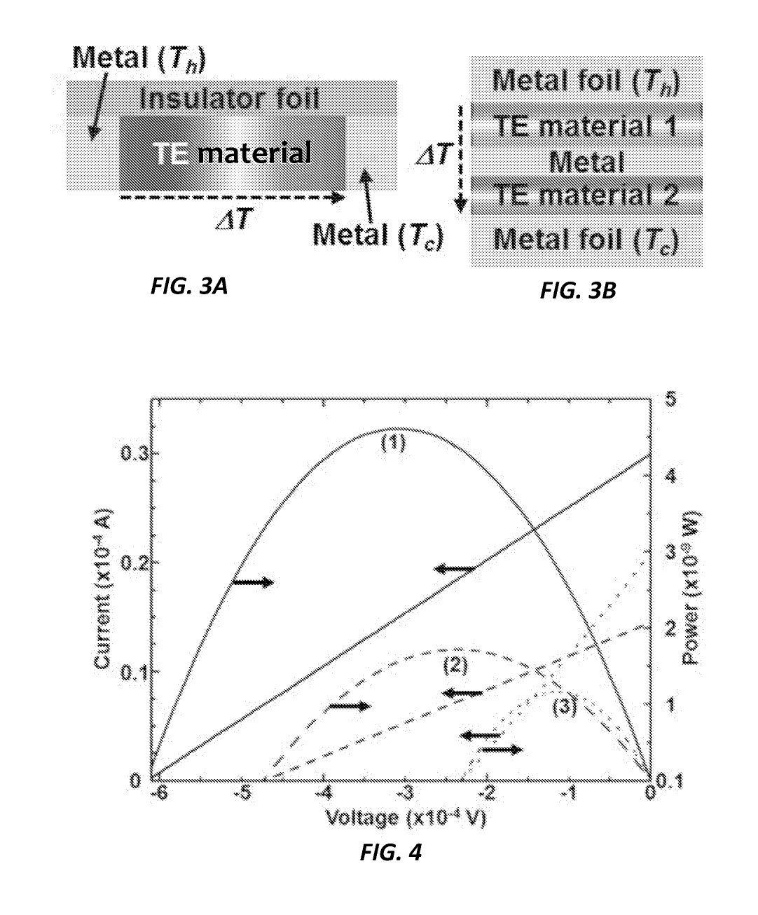

In a further embodiment, multiple TEGs optimized for specific T are placed at various positions with appropriate ΔT on a light absorber/heat generator. The current invention includes unique TEG configurations, with vast 3D scalability in both “lateral” and “vertical” directions. A laterally-scaled TEG (L-TEG) (i.e. large area TEG) is obtained by employing a microcrystal TE film deposition processes on insulator foils as large as required (see FIG. 3A). A vertically-scaled TEG is provided by assembling multiple TEG stacks on top of each other as many times as desired (see FIG. 3B), using the microcrystal TE film deposition process on metal foils.

According to another aspect of the invention, the thermoelectric generator includes at least one p-type semiconductor and at least one n-type semiconductor, where each p-type semiconductor and each n-type semiconductor abut a planar surface of the light absorbing and heat generating element.

In a further aspect of the invention, the thermoelectric generator includes a microcrystal TE film deposited on an insulator foil. An insulator foil refers to those that are either thermally or electrically insulating, or those that are both thermally and electrically insulating. In one aspect, the microcrystal TE film is a material that includes those containing group III and V (e.g. gallium arsenide), group II and VI (zinc oxide), group V and VI (e.g. BiTe), and group IV (e.g Si, Ge) on the Periodic Table. In a further aspect, the thermoelectric generator includes a stack of at least two microcrystal TE films deposited on the insulator foil. In another aspect, the insulator foil is a material that includes oxides (e.g. aluminum oxide), nitrides (e.g. aluminum nitride), and carbides (e.g. silicon carbide) and their respective compounds either in their crystalline phases or non-crystalline phases.

In a further aspect of the invention, the thermoelectric generator includes a microcrystal TE film deposited on a conductor foil. A conductor foil refers to those that are either thermally or electrically conducting, or those that are both thermally and electrically conducting. In one aspect, the microcrystal TE film is a material that includes those containing group III and V (e.g. gallium arsenide), group II and VI (zinc oxide), group V and VI (e.g. BiTe), and group IV (e.g Si, Ge) on the Periodic Table. In a further aspect, the thermoelectric generator includes a stack of at least two microcrystal TE films deposited on the conductor foil. In another aspect, the conductor foil is a material that includes transparent conducting oxides (e.g. indium tin oxide), nitrides (e.g. titanium nitride), and carbides (e.g. tungsten carbide) and their respective compounds either in their crystalline phases or non-crystalline phases.

FIG. 4 shows a graph of experimental current-voltage and associated electrical power profiles generated by (1) quadruple- (2) double-, (3) single-stack modules fabricated by stacking four, two, and one TEG, respectively. For a given ΔT=18° C./stack, generated electrical power was found to scale with the number of stacks, clearly demonstrating the vertical scaling. Lateral and vertical scaling have been demonstrated by the inventors, according to the current invention.

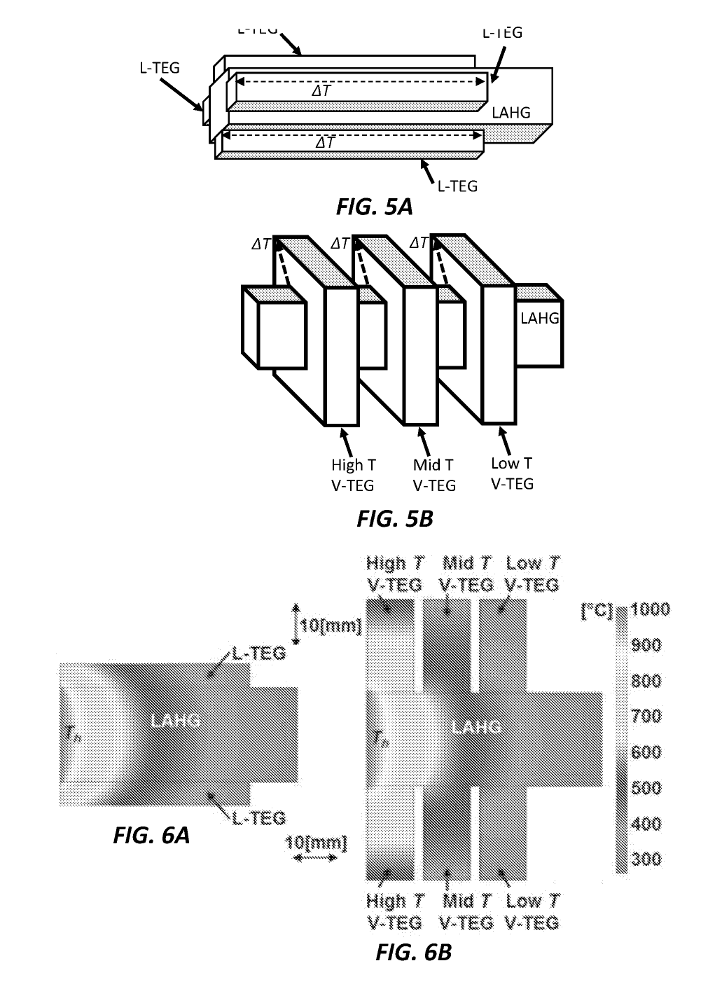

FIGS. 5A-5B show two exemplary embodiments of the invention that employ (FIG. 5A) L-TEGs and (FIG. 5B) V-TEGs. In both examples, CS illuminates the left side of the light absorber/heat generator (LAHG), creating ΔT in the direction indicated by the dotted arrows, where the number of L- or V-TEGs in FIGS. 5A and 5B is merely a representation and not a limitation. The notable feature in the current invention relates to multiple TEGs monolithically integrated on a LAHG via film deposition processes, rather than mechanical attachment, providing seamless thermal contact between the two parts. FIGS. 6A-6B show temperature distribution maps across two types of the invention that are similar to those in FIGS. 5A-5B. The maps were obtained by steady-state finite-element analysis with two boundary conditions: Tₕ was fixed to 1000° C. and heat was dissipated through the peripheral via radiative emission to the environment that acted as a blackbody absorber at 23° C. FIG. 6A visibly shows that ΔT generated across the LAHG “induces” ΔT across the L-TEGs; in addition, FIG. 6B evidently reveals that different portions of ΔT generated across the LAHG are “tapped” by three types of V-TEGs, showing first order validation of the invention.

FIG. 3A shows that electrical current is forced to flow through a film along ΔT and is limited by the thickness of a TE material. In one aspect, the microcrystal TE materials exhibited electrical, not thermal, behavior similar to that of their bulk counterparts when their thickness goes beyond a critical thickness. This is mitigated by optimizing the TE material thickness, and optimizing the distance over which ΔT is generated to improve the efficiency. For V-TEGs, this is demonstrated in FIG. 4. In this example, the series electrical resistance was found to deteriorate the efficiency. Using semiconductor film deposition, L- or V-TEGs are directly deposited on the LAHG, mitigating risks of mechanical failures associated with dissimilar materials unified as a single piece that undergoes high T and large ΔT. In one embodiment, area selective film deposition that allows deposition to occur only within specific areas on a LAHG is used to accomplish the monolithic integration of TEGs made of different materials.

The invention is expected to bring significant benefits to applications in which the electro-magnetic (EM) wave from the sun (i.e. sunlight) serves as a source of energy that will be converted into heat, and then, the heat is further converted into electric power via thermoelectric generators (TEGs), which is often referred to as Solar TEG. In a range of STEG architectures that have been proposed and/or demonstrated, conventional TEG modules are modified so that the hot side of a TEG module absorbs sunlight and converts it into heat, and such conventional TEG modules are merely coupled with an optics that focuses sunlight onto the hot side of a TEG module. One of the major disadvantages of conventional TEG modules used in Solar TEG applications becomes apparent when the following fact is considered: a specific TE material exhibits good performance within a narrow range of temperatures, where there exists an optimum temperature range.

The current invention establishes a large temperature gradient across a structure, and uses various TE materials tuned for different optimum temperature ranges, which improves overall performance over using a single TE material. Therefore, the current invention improves the performance of Solar TEG by implementing the following two factors simultaneously: a large temperature gradient and multiple TE materials. The current invention is an improvement over conventional Solar TEG architectures, which have two major shortcomings: (1) a large temperature gradient cannot be readily formed and (2) various TE materials cannot be easily integrated. The current invention provides (1) an absorber that captures electro-magnetic waves and converts them into a temperature gradient and (2) has multiple thermoelectric (TE) devices monolithically integrated on the absorber, making TEGs highly suitable for Solar TEG applications.

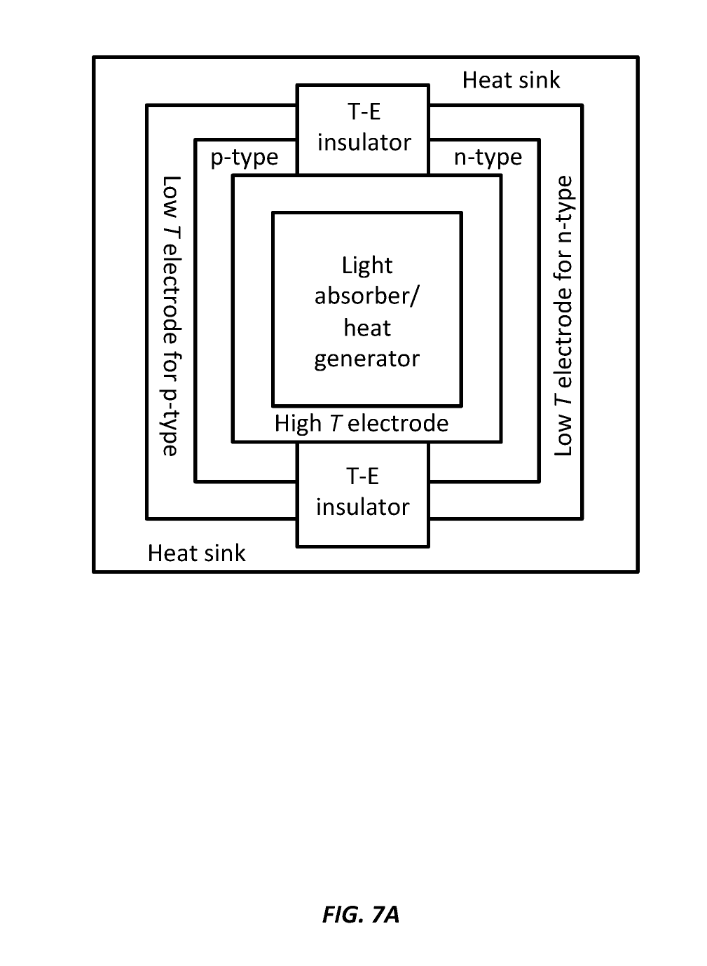

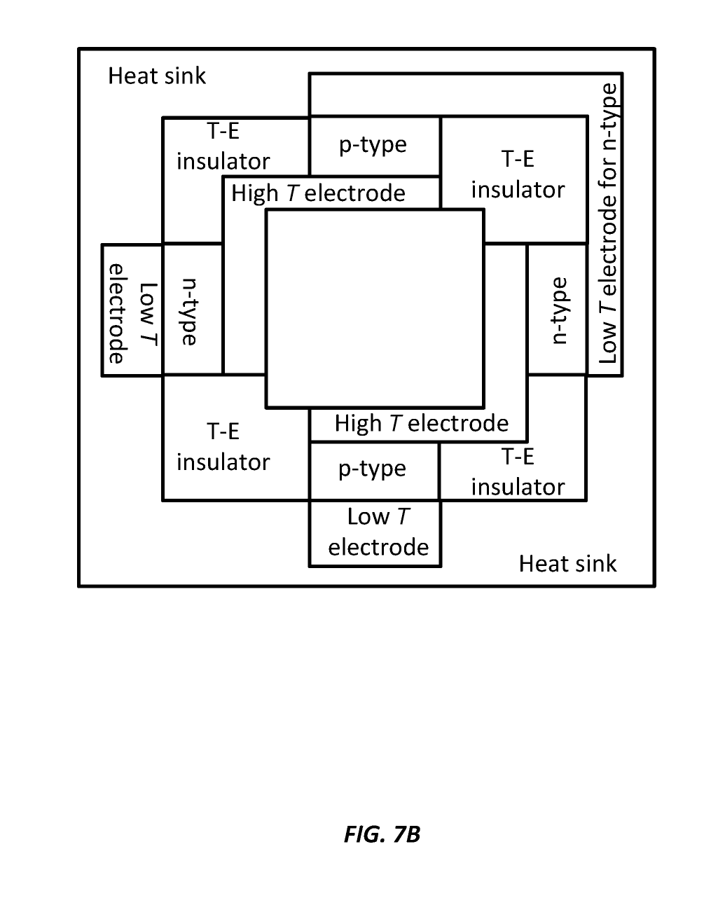

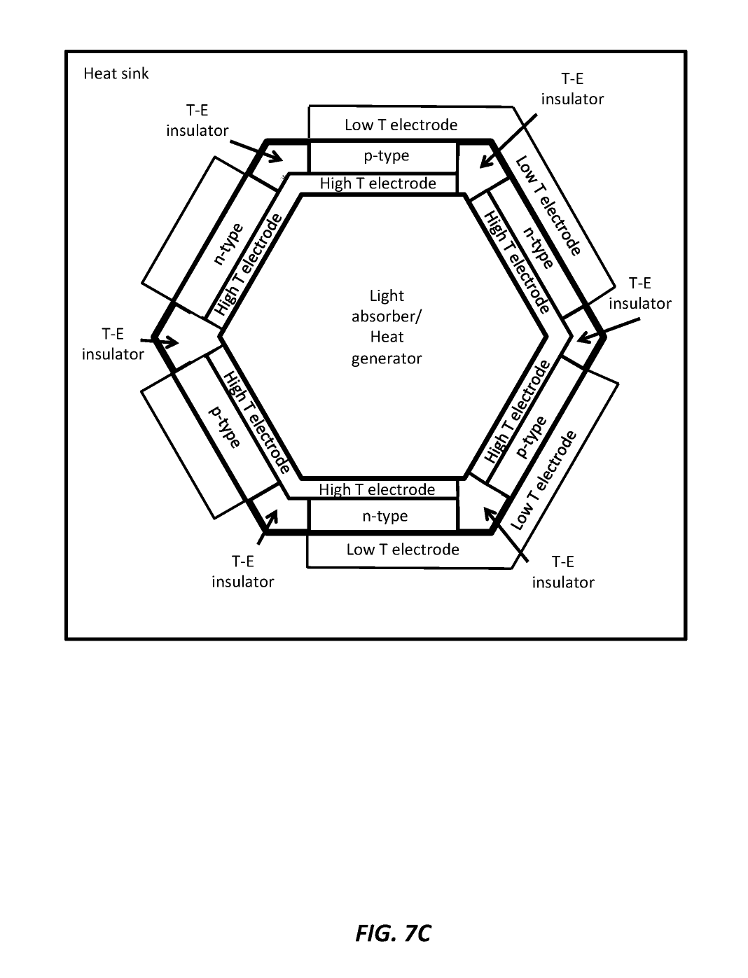

The embodiment shown in FIG. 2 shows a relatively long light absorber/heat generator that is heated by illuminating the left side with concentrated sunlight, creating, a steady-state temperature gradient from the left to the right. Exemplary TE devices made of different materials and optimized for different temperature ranges are monolithically integrated on the absorber, where FIGS. 7A-7C show cross-sectional images revealing the internal structures at one of the TE sections. FIG. 7A shows two TE legs having one p-type and one n-type, FIG. 7B shows four TE legs having two p-type and two n-type, and FIG. 7C shows six TE legs having three p-type and three n-type, where these examples show the leg structure extending to any practical number, and the variations in the number of TE legs show in these figures are just examples and not a limitation to adjust open circuit voltage.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example, the configurations shown in FIGS. 7A-7C do not necessarily have to have two opposite types, in other words, a p-type semiconductor can be replaced by an n-type semiconductor, or an n-type semiconductor can be replaced by a p-type semiconductor with appropriate modifications on the routing of electrical and thermal paths. Furthermore, the total number of n-type and p-type segments is not limited to those shown in FIG. 7A-7C, but it can be arbitrary depending on the diameter of a light/absorber/heat generator and the size of n-type and/or p-type segments.

All such variations are considered to be within the scope and spirit of the present invention as defined by the following claims and their legal equivalents.

What is claimed:

1) A solar-powered thermoelectric generator, comprising:
a) a solar collector;
b) a light absorbing and heat generating element, wherein said light absorbing and heat generating element comprises an elongated shape, wherein a first end of said light absorbing and heat generating element is configured to absorb light from said solar collector, wherein said absorbed light converts to heat in said light absorbing and heat generating element, wherein said light absorbing and heat generating element is configured to form a thermal gradient along a length of said light absorbing and heat generating element from said first end of said light absorbing and heat generating element to a second end of said light absorbing and heat generating element; and
c) a plurality of thermoelectric generators, wherein said plurality of thermoelectric generators are disposed along said light absorbing and heat generating element, wherein said first end of said light absorbing and heat generating element is hotter than said second end of said light absorbing and heat generating element.

2) The solar-powered thermoelectric generator of claim 1, wherein said light absorbing and heat generating element comprises a material selected from the group consisting of single element materials, multi-primary element materials, oxides, nitrides, and carbides, wherein said single element materials comprise graphite, wherein said multi-primary element materials comprise Inconel superalloy, wherein said oxide comprises aluminum oxide, wherein said nitrides comprise aluminum nitride, wherein said carbides comprise silicon carbide

3) The solar-powered thermoelectric generator of claim 1, wherein said thermoelectric generator comprises at least one p-type semiconductor and at least one n-type semiconductor, wherein each said p-type semiconductor and each said n-type semiconductor abut a planar surface of said light absorbing and heat generating element.

4) The solar-powered thermoelectric generator of claim 1, wherein said thermoelectric generator comprises a microcrystal TE film deposited on an insulator or conductor foil.

5) The solar-powered thermoelectric generator of claim 4, wherein said microcrystal TE film comprises a material selected from the group consisting of group III and group V materials, group II and group VI materials, group V and group VI materials, and group IV materials.

6) The solar-powered thermoelectric generator of claim 5, wherein said group III and group V materials comprise gallium arsenide, wherein said group II and group VI materials comprise zinc oxide, wherein said group V and group VI materials comprise BiTe, wherein said group IV materials comprise Si or Ge.

7) The solar-powered thermoelectric generator of claim 4, wherein said thermoelectric generator comprises a stack of at least two said microcrystal TE film deposited on said insulator or conductor foil.

8) The solar-powered thermoelectric generator of claim 4, wherein said insulator or conductor foil comprises a material selected from the group consisting of insulating oxides, insulating nitrides, insulating carbides, transparent conducting oxides, conducting nitrides, and conducting carbides.

9) The solar-powered thermoelectric generator of claim 8, wherein said insulating oxides comprise aluminum oxide, wherein said insulating nitrides comprise aluminum nitride, wherein said insulating carbides comprise silicon carbide, wherein said transparent conducting oxides comprise indium tin oxide, wherein said conducting nitrides comprise titanium nitride, wherein said conducting carbides comprise tungsten carbide.

10) The solar-powered thermoelectric generator of claim 1, wherein each said thermoelectric generator is configured to wrap around said light absorbing and heat generating element.

11) The solar-powered thermoelectric generator of claim 1, wherein each said thermoelectric generator is configured to match a temperature range along said light absorbing and heat generating element.

12) The solar-powered thermoelectric generator of claim 1, wherein each said thermoelectric generator is disposed longitudinally to said light absorbing and heat generating element.

13) The solar-powered thermoelectric generator of claim 1, wherein each said thermoelectric generator is disposed transverse to said light absorbing and heat generating element.

14) The solar-powered thermoelectric generator of claim 1, wherein said solar-powered thermoelectric generator is coupled to a heat sink, wherein said heat sink conducts heat from said light absorbing and heat generating element and through said thermoelectric generator.
